(19) United States
(12) Patent Application Publication
(10) Pub. No.: US 2014/0036592 A1
(43) Pub. Date: Feb. 6, 2014

(54) SEMICONDUCTOR STORAGE DEVICE

(71) Applicant: KABUSHIKI KAISHA TOSHIBA, Tokyo (JP)

(72) Inventors: Haruo MIKI, Kanagawa (JP); Kenji SAWAMURA, Kanagawa (JP); Koki UENO, Kanagawa (JP)

(73) Assignee: Kabushiki Kaisha Toshiba, Tokyo (JP)

(21) Appl. No.: 13/779,575

(22) Filed: Feb. 27, 2013

(30) Foreign Application Priority Data
Aug. 6, 2012 (JP) 2012-174473

(51) Int. Cl. G11C 16/04

(52) U.S. Cl. CPC G11C 16/04
USPC 365/185.17; 365/185.18

(57) ABSTRACT

A semiconductor storage device has a memory cell array including memory cells and a plurality of redundancy regions arranged in a first direction including flag cells, plural word lines extending in the first direction, and plural bit lines extending in a second direction crossing the first direction, and a controller configured to control writing of data to the memory cells and also to the flag cells.

### CROSS-REFERENCE TO RELATED APPLICATION

This application is based upon and claims the benefit of priority from Japanese Patent Application No. 2012-174473, filed Aug. 6, 2012, the entire contents of which are incorporated herein by reference.

### FIELD

Embodiments described herein relate generally to a semiconductor storage device. In particular, the present disclosure relates to a nonvolatile semiconductor storage device having redundant regions in a memory cell array.

### BACKGROUND

Nonvolatile semiconductor storage devices have a memory cell array region and redundant regions arranged in the memory cell array region. In the memory cell array region, memory cells that store the user data are arranged. When defects occur in the memory cell array region, it is possible to replace the defective cells by using spare cells. On the other hand, there may be the case when the defective cells cannot be replaced by the spare cells. For example, if the redundant regions are concentrated at a single site, it is possible that the nonvolatile semiconductor storage device may become defective if a defect, due to, for example, particles or the like during manufacturing, occurs at or near the site where the redundant regions are concentrated. If the nonvolatile semiconductor storage device has concentrated redundant regions, then manufacturing yield may therefore suffer due to a lack of defect tolerance.

### DESCRIPTION OF THE DRAWINGS

FIG. 1 is a constitution diagram depicting an example of a nonvolatile semiconductor storage device according to a first embodiment.

FIG. 2 is a block diagram depicting an example of a memory cell array according to the first embodiment.

FIG. 3 is a block diagram depicting another example of the memory cell array according to the first embodiment.

FIG. 4 is a circuit diagram depicting an example of the memory cell array according to the first embodiment.

FIG. 5 is a circuit diagram depicting another example of the memory cell array according to the first embodiment.

FIG. 6A is an example of a cross-sectional view illustrating a memory cell according to the first embodiment. FIG. 6B is an example of a cross-sectional view depicting a peripheral transistor according to the first embodiment.

FIG. 7 is a cross-sectional view depicting an example of a cross-section of the semiconductor storage device according to the first embodiment.

FIG. 8 is a diagram depicting an example of voltages fed to various regions depicted in FIG. 7.

FIG. 9A, FIG. 9B are diagrams depicting an example of threshold distribution of the memory cells according to the first embodiment.

FIG. 10A and FIG. 10B are diagrams depicting an example of the threshold distribution of the memory cells according to the first embodiment.

FIG. 11 is a flow chart depicting an example of a data write operation of a low-order page of the semiconductor storage device according to the first embodiment.

FIG. 12 is a flow chart depicting an example of the data write operation of a high-order page of the semiconductor storage device according to the first embodiment.

FIG. 13 is a flow chart depicting an example of a data read operation of the low-order page of the semiconductor storage device according to the first embodiment.

FIG. 14A is a diagram depicting an example of a connection relationship between word lines and a word line controller according to the first embodiment.

FIG. 14B is a diagram depicting another example of a connection relationship between word lines and a word line controller according to the first embodiment.

FIG. 15 is a diagram depicting an example of a configuration of redundant regions according to the first embodiment.

FIG. 16 is a diagram depicting an example of the configuration of the redundant regions according to the first embodiment.

FIG. 17 is a diagram depicting an example of a third flag determination method according to the first embodiment.

### DETAILED DESCRIPTION

Embodiments of present disclosure provide a semiconductor storage device that can manufactured with increased yield. In general, the embodiments of the present disclosure will be explained with reference to figures.

An example of a semiconductor storage device of the present disclosure has a memory cell array including memory cells and a plurality of redundancy regions arranged in a first direction including flag cells, plural word lines extending in the first direction, bit lines extending in a second direction crossing the first direction, and a controller. Different memory cells and flag cells are commonly connected by each of the word lines, and the redundant regions are dispersed in the memory cell array.

A NAND-type flash memory will be explained as an example of the semiconductor storage device of this embodiment.

The NAND-type flash memory has a memory cell array 1 with memory cells MC arranged in a matrix configuration. This memory cell array 1 has bit lines BL, word lines WL, common source line CELSRC, and memory cells MC. Each memory cells MC can store n-bits (n is a natural number of 2 or larger) of data.

Various types of commands CMD, addresses ADD, and data DT for controlling the operation of the NAND-type flash memory are fed from a host memory controller HM are input into an IO buffer 4. The write data input into the IO buffer 4 are fed via a data input/output lines IO to IOn to the bit lines BLs are selected by a bit line controller 2. Here, the various commands CMD and addresses ADD are input into the controller 5, and controller 5 then controls a voltage supply circuit 6 and a driver 7 on the basis of the commands CMD and the addresses ADD. For example, the commands can include the control signal ALE (address latch enable), CLE (command latch enable), WE (write enable), and RE (read enable).

Under control of the controller 5, the voltage supply circuit 6 generates the voltages needed to write, read, and erase, and then applies the voltages to the driver 7. Under control of the controller 5, the driver 7 supplies these voltages to the bit line controller 2 and word line controller 3. The bit line controller 2 and word line controller 3 read the data from the memory cells MC using the voltages; they also write the data in the memory cells MC and carry out the process of erasing the data of the memory cells MC.

Connected to the memory cell array 1 are the bit line controller 2 for controlling the voltage of the bit lines BL and the word line controller 3 for controlling the voltage of the word lines WL. Also, the bit line controller 2 and the word line controller 3 are connected to the driver 7.

That is, the controller 5 controls the driver 7, the driver 7 controls the bit line controller 2 on the basis of the addresses ADD, and the data of the memory cells MC in the memory cell array 1 are read via the bit lines BL. Also, the controller 5 controls the driver 7, the driver 7 controls the bit line controller 2 on the basis of the addresses ADD, and it carries out the process of writing in the memory cells MC in the memory cell array 1 via the bit lines BL.

In portions of the explanation, the bit line controller 2, the word line controller 3, the driver 7, and the controller 5 may be referred to en bloc as “controller.”

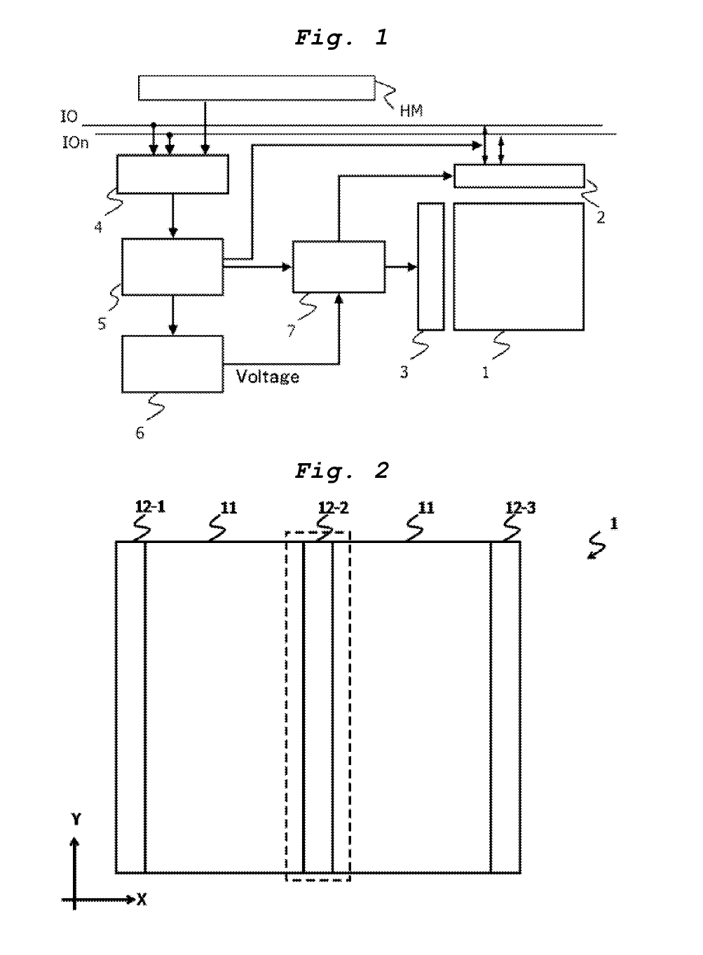

FIG. 2 is a block diagram illustrating an example of the memory cell array 1. The X-direction may also be called the row direction or word line direction, and the Y-direction may also be called the column direction or bit line direction.

The memory cell array 1 has plural memory cell array regions 11 and redundant regions 12-1 to 12-3 that sandwich the memory cell array regions 11. Here, the redundant regions 12 are regions wherein flag cells FC are arranged. The flag cells FC store operation parameters, spare cells, etc. The flag cells FC are presented as an example. The area of the redundant regions 12 is generally smaller than the area of the memory cell array regions 11.

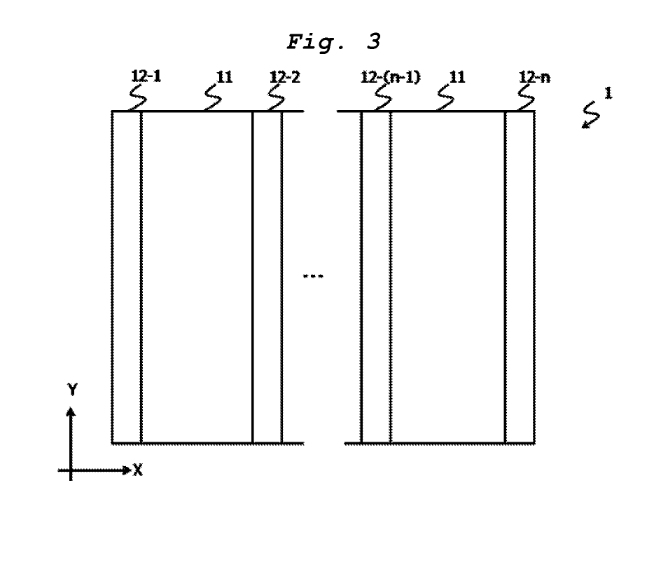

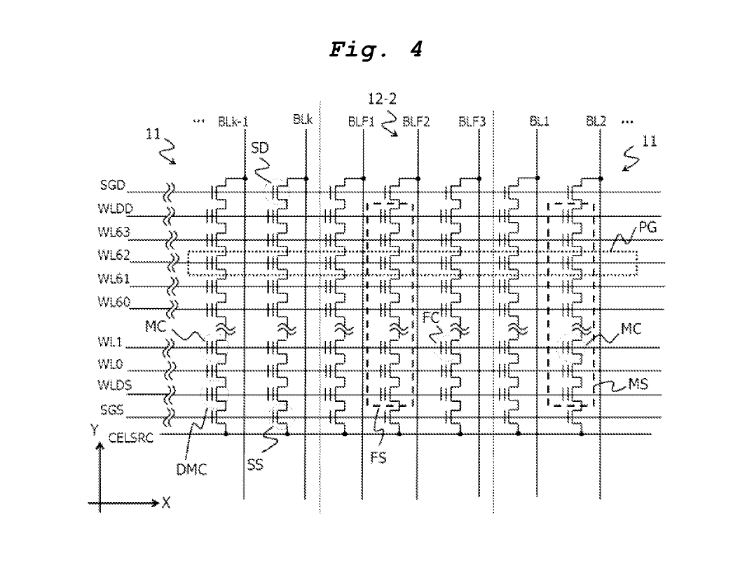

The number of the redundant regions 12 is not limited to 3, as depicted in FIG. 3. There may be n (n is a natural number of 2 or larger) in the plural memory cell array regions 11 in the Y-direction. Also, the redundant regions 12 do not need to be arranged in the end portions of the memory cell array 1. Instead, dummy regions may be arranged there. Here, the dummy regions refer to the regions where dummy (memory) cells not intended to store data are arranged.

FIG. 4 is a circuit diagram of an example of the memory cell array according to this embodiment. FIG. 4 is a circuit diagram of the portion surrounded by broken line in FIG. 2. Plural memory cells MC are arranged in the memory cell array regions 11. In each memory string MS, for example, 64 memory cells MC are connected in tandem (series) in a bit line direction. Also, a NAND string includes the memory string MS and selecting transistors SD, SS. In addition, dummy memory cells DMC may be arranged between the memory string and the selecting transistor SD and between the memory string and the selecting transistor SS.

Memory strings MS are arranged in a word line direction (the number of memory strings is a number of k, where k is a natural number of 2 or larger); one of the bit lines BL is electrically connected to one end of the memory string MS, and the common source line CELSRC is electrically connected to the other end of the memory string. Also, NAND strings NS are arranged in the word line direction, and one of the bit lines BL is connected to one end of the NAND strings NS. The common source line CELSRC is connected to the other end of the NAND string NS. The selecting transistors SD, SS are connected to selecting gate lines SDG, SGS.

Flag cells FC are arranged in the redundant region 12-2 into flag strings FS. A flag string FS includes, for example, 64 flag cells FC connected in series in the bit line direction. Here, each NAND flag string includes the flag string FS and the selecting transistors SD, SS. In addition, dummy memory cells DMC may also be arranged between the flag string FS and the selecting transistor SD and between the memory string and the selecting transistor SS.

Plural flag strings FS (e.g., 3 as shown in FIG. 4) are arranged in the X direction (word line direction). One of the plural bit lines BL is electrically connected to one end of the flag strings FS, and the common source line CELSRC is electrically connected to the other end. Also, plural NAND flag strings are arranged in the word line direction, one of a plural bit lines BL is connected to one end of the NAND flag strings, and the common source line CELSRC is connected to the other end.

The bit lines BL are connected to the data latches arranged in the bit line controller 2. The data input from the host or memory controller HM are temporarily stored in the data latches.

Here, the units of the NAND strings NS and the NAND flag string in the word line direction are called block BLK.

The word lines WL extend in the word line direction, and the memory cells MC and flag cells FC arranged adjacently in the word line direction are commonly connected. The memory cells MC and the flag cells FC connected in the word line direction form a page. Writing the memory cells MC is carried out in page units. In addition, one should pay attention to the fact that the “page” of the writing unit is a concept different from the “low-order page” and “high-order page.” The writing bit levels of the data will be explained later.

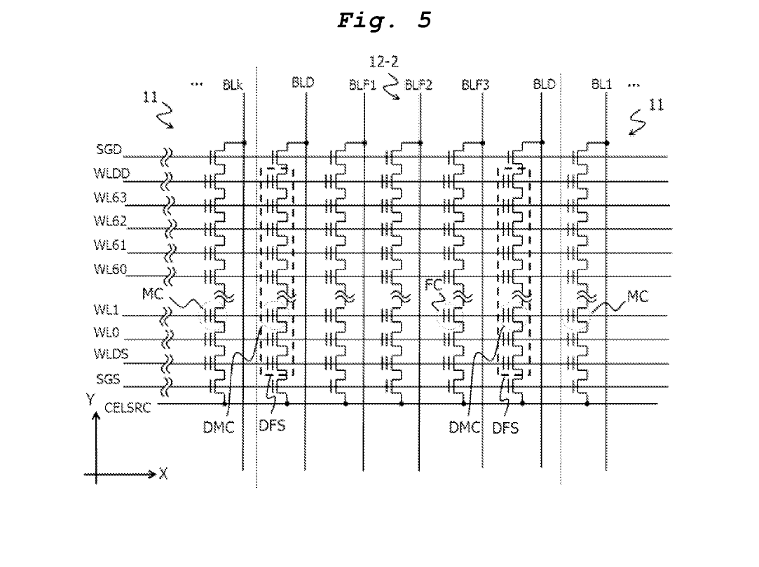

The numbers of the flag strings FS arranged in the various redundant regions 12 may be different from each other. Also, as shown in FIG. 5, dummy flag string DFS may be arranged between the redundant regions 12 and the memory cell array regions 11. The dummy flag string DFS may be composed of, for example, 64 dummy memory cells DMC connected in tandem in the bit line direction. Because the memory cells MC and the flag cells FC have different functions from each other, the data patterns stored in them are also different. For example, because the memory cells MC store the user data, in many cases, a random data pattern is stored. On the other hand, because the flag cells FC store the data for determining the “low-order page” or “high-order page,” usually, a regular data pattern is stored in them.

Here, by arranging the dummy flag string DFS between the redundant regions 12 and the memory cell array regions 11, interference between the regions with different data patterns can be prevented. As a result, it is possible to improve the reliability of the data stored in the memory cells MC and the flag cells FC.

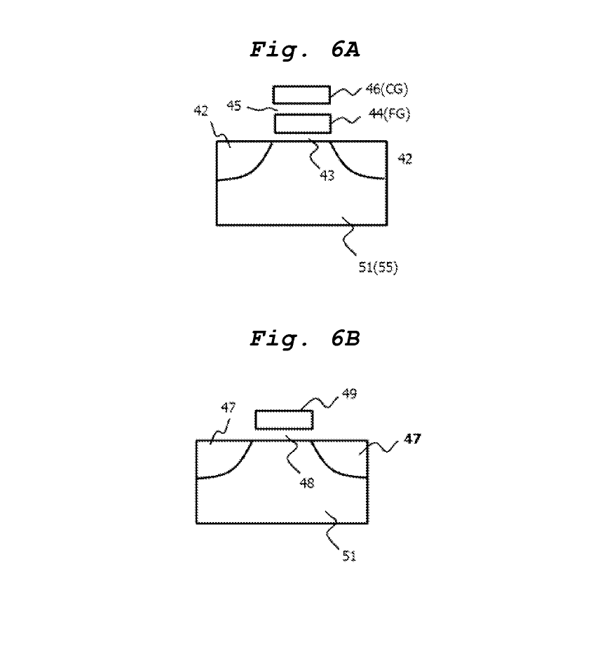

FIG. 6A and FIG. 6B are cross-sectional views illustrating an example of the MOS transistors arranged in the memory cells MC and those arranged in the peripheral circuits, respectively. On a substrate 51 (or P-type well region 55 to be explained later), an n-type diffusion layer 42 is formed as the source and drain of the memory cells MC. For example, the substrate 51 is a P-type semiconductor substrate. On the P-type well region 55, a charge accumulating layer (FG) 44 is formed via a gate-insulating film 43. On this charge-accumulating layer 44, a control gate (CG) 46 is formed via an insulating film 45. On the substrate 51, an n-type diffusion layer 47 is formed as the source and drain. On the substrate 51, a control gate 49 is formed via a gate-insulating film 48. The film thickness of the gate insulating film 48 can be thicker than the film thickness of the gate-insulating film 43.

By accumulating charge in the charge-accumulating layer (FG), it is possible to change the threshold voltage of the memory cells MC. By allocating the data corresponding to the threshold voltage, it is possible to store the data. Usually, plural memory cells are adopted to store a large amount of data. As a result, the threshold of the memory cells forms a threshold distribution corresponding to the various data.

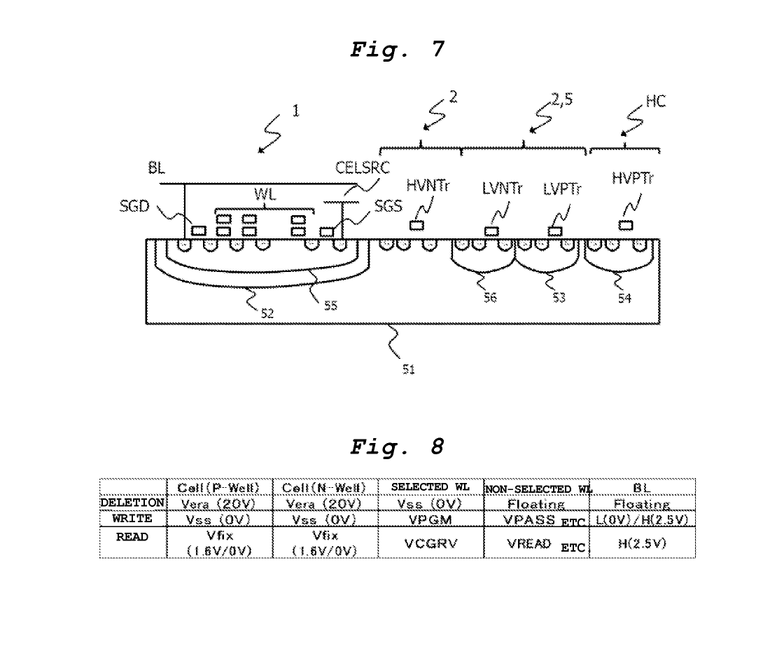

FIG. 7 is a cross-sectional view illustrating an example of the NAND flash memory. For example, in the substrate 51, n-type well regions 52, 53, 54 and P-type well region 56 are formed. A P-type well region 55 is formed in the n type well region 52. In this P-type well region 55, the memory cells MC forming the memory cell array 1 are shown. In addition, in the n-type well region 53 and the P-type well region 56, there are the low-voltage P-type MOS transistor LVPTr and low-voltage n-type MOS transistor LVNTr arranged in the bit line controller 2 or the controller 5, etc. In the substrate 51, for example, there is the high-voltage n-type MOS transistor HVNTr that connects the bit line BL and the sense amplifier arranged in the bit line controller 2. In addition, in the n-type well region 54, for example, there is the high voltage p-type MOS transistor HVPTr arranged in the discharge circuit HC or the like. As shown in FIG. 5, the high-voltage transistors HVNTr, HVPTr have a thicker gate-insulating film than the low-voltage transistors LVNTr, LVPTr.

FIG. 8 shows an example of the voltages fed to the various regions shown in FIG. 7. The voltages shown in FIG. 8 are fed to the various regions for the erasure operation, the program operation, and the read operation. Here, Vera is the voltage applied on the substrate during data erasure; Vss is the ground voltage GND; and the Vpgmh is the voltage applied on the word line during the data write operation.

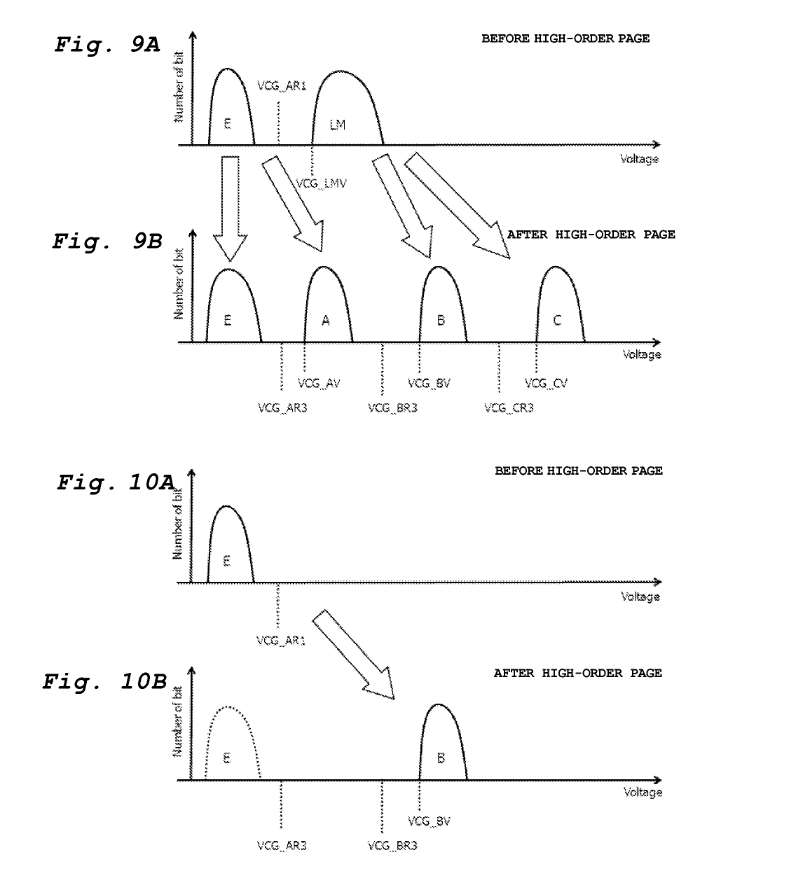

In the following, with reference to FIGS. 9 to 12, the data write method of the NAND flash memory according to an embodiment of the present disclosure will be explained. The write operation includes the program operation with the write voltage applied, as well as the verify operation for checking the threshold voltage of the memory cells MC after program operation. However, it is not a necessity to carry out the verify operation after the program operation. For example, performing the verify operation once after plural rounds of the program operation may be adopted.

For example, when 2 bits are stored in one memory cell MC, as shown in FIG. 9B, the threshold of the plural memory cells MC have a 4-threshold distribution. Here, the levels are called “E” level (referring to the erasure state), then “A” level, “B” level, and “C” level (referring to the rising order of the threshold voltage). Here, for the NAND flash memory, as in the write operation, the so-called LM write system is adopted to decrease the variation in the threshold caused by coupling between the charge-accumulating layers.

For the LM write system, for example, when the 2-bit (4-value) data are recorded in a memory cell MC, there is the system of writing performed by dividing between the low-order page and high-order page. FIG. 9A and FIG. 9B show an example of the threshold distribution of the memory cells MC.

First of all, as shown in FIG. 9A, in the data writing of the low-order page, the controller 5 controls that the write voltage with a 2-threshold distribution is available. Here, writing is carried out for the “1” data and “0” data. The “0” data is allotted to the “LM” level as the intermediate threshold level about between the “A” level and the “B” level. The “1” data is allotted to the “E” level as the erasure state. The verification operation of the “LM” level on the low-order page is carried out as the verification voltage is VCG_LMV. In addition, the “LM” level is read by using the read voltage VCG_AR1, which is the intermediate voltage between the “E” level and the “LM” level. This voltage may be the same as the read voltage of the intermediate voltage between the “E” level and the “A” level.

After the data write process of the low-order page, data writing of the high-order page is carried out. As shown in FIG. 9B, in writing the high-order page, the write voltage is controlled so that the controller 5 has a 4-threshold value distribution. “A” level is obtained by changing the threshold voltage from the “E” level, and the “B” and “C” levels are obtained by changing the threshold voltage from the “LM” level. As a result, the 4-value threshold distribution is realized. In addition, for the data, the “11” data are assigned to the “E” level, the “01” data are assigned to the “A” level; the “10” data are assigned to the “C” level. Here, for the “XY” data, the right-hand side (Y) represents the low-order page data, and the left-hand (X) side represents the high-order page data. In addition, the verification operation on the “A”, “B” and “C” levels on the high-order page is carried out with the verify voltages set at VCG_AV, VCG_BV, VCG_CV (VCG_AV<VCG_BV<VCG_CV), respectively.

Here, there are the following cases: the case 1 when the LM write system is adopted; the case of the erasure state when writing the low-order page is also not carried out; the case 2 when writing ends only for the low-order page before writing the high-order page (the cases 1 and 2 may be called “before high-order page); and the case 3 when writing ends after the high-order page (the case 3 may be called “after high-order page”). As a result, it is necessary to determine whether the writing occurs before the high-order page or after the low-order page. Here, the controller 5 controls the data that are stored in the flag cells FC in writing the high-order page, and the data are used to determine whether it is before the high-order page or after the high-order page.

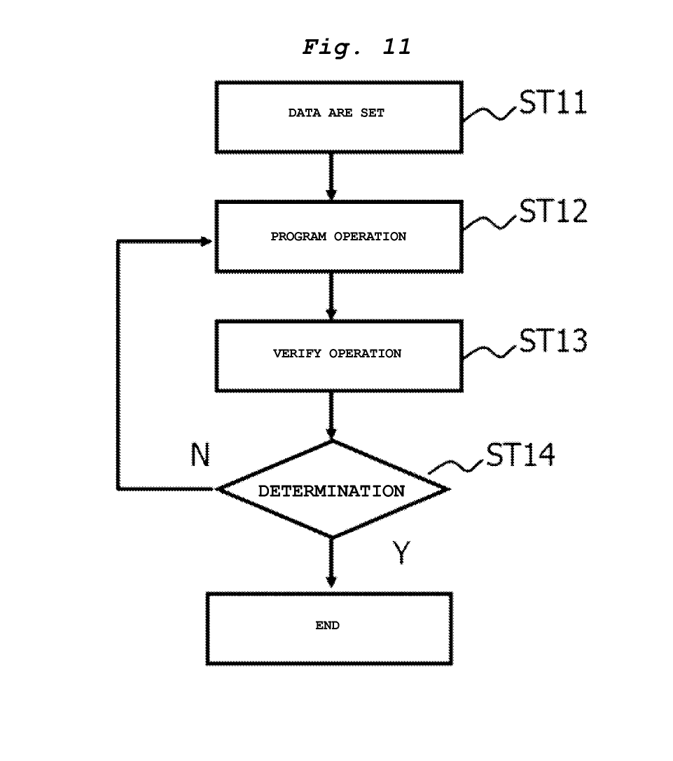

FIG. 10A and FIG. 10B show an example of the threshold distribution of the flag cells FC. In the case of writing the high-order page, the flag cells FC are written on the “B” level. That is, the flag data of the flag cells FC are assigned to the “B” level. This determination is made based on whether it is after the high-order page or before the high-order page and whether the threshold voltage of the flag cells FC is higher or lower than the read voltage VCG_BR3. In this case, it is also possible to determine the threshold voltage by using the read voltage VCG_AR3. More specifically, in the read operation, the read voltage is set at read voltage VCG_BR3 to determine the threshold voltage of the flag cells FC. Under this condition, if the result of the read operation of flag cells FC is “0” data, the function occurred after the high-order page; alternately, if the result is “1” data, it occurred before the high-order page.

In addition, the flag data of the flag cells FC may be assigned to the “A” level. In this case, determining whether the function occurred after the high-order page or before the high-order page is carried out based on whether the threshold voltage of the flag cells FC is higher or lower than the read voltage VCG_AR3. More specifically, in the read operation, the read voltage is set at VCG_AR3 to determine the threshold voltage of the flag cells FC. Under this condition, if the result of read of the flag cells FC is “0” data, it is after the high-order page, and if the result is “1” data, it is before the high-order page.

In the following, data write of the low-order page will be explained with reference to FIG. 11. Here, FIG. 11 is a flow chart illustrating an example of the data write operation of the low-order page.

### (Data Set: ST11)

The program operation of the low-order page has the addresses ADD sent from the host or memory controller HM. According to the addresses ADD, the controller 5 and the word line controller 3 select one page PG from the plural pages shown in FIG. 4. This page is called selected page PGs.

Then, the write data DT are input from the host or memory controller HM and are stored in the data latches in the bit line controller 2 (ST11).

### (Program Operation: ST12)

As the write command is input from the host or memory controller HM, the data write operation in the memory cells MC is started. For example, when “1” data are stored in the data latch (i.e., the write operation is not carried out), the bit line BL connected to the data latch is applied with voltage Vdd (e.g., 2.5 V) by the controller 5. When the “0” data are stored in the data latch (i.e., the write operation is carried out), the bit line BL connected to the data latch is applied with the ground voltage Vss (e.g., 0 V) by the controller 5.

In the write operation of the low-order page, the process of data write to the flag cells FC is not carried out. Consequently, the host or memory controller HM sends “1” data (in which the write operation is not carried out) to the data latch of the bit line BL connected to the flag cell FC. Also, the controller 5 sets “1” data in the data latch of the bit line BL connected to the flag cell FC.

The controller 5 applies the Vdd on the select gate line SGD of the selected block, applies the write voltage VPGM (such as 20 V) on the word line WL (selected word line WLs) of the selected page PGs, and applies the passing voltage VPASS (10 V) on the non-selected word line WLns (i.e., those other than the selected word line WLs). As a result, when the bit line BL is at Vss, the channel of the cell becomes Vss, and the selected word line WLs becomes the write voltage VPGM, so that charge is injected in the memory cell MC. On the other hand, when the bit line is at voltage Vdd, the channel of the cell is not at the ground voltage Vss; by the so-called self boost, it becomes, for example, about the write voltage VPGM/2. As a result, charge is not injected into the memory cell MC.

When the data stored in the data latch is the “0” data, as shown in FIG. 9A, the threshold voltage of the memory cells MC increases, and the threshold voltage of the memory cells MC increases to the “LM” level. Also, when the data stored in the data latch are “1” data, the threshold voltage of the memory cells MC does not change, and the threshold voltage of the memory cells MC keeps the “E” level.

### (Verify Operation: ST13)

After the program operation, the verification operation is carried out. The controller 5 and the bit line controller 2 charge the bit lines BL to the high level. The controller 5 applies a verification voltage VCG_LMV to the selected word line WLs. In addition, the controller 5 applies a read voltage Vread a little higher than the upper limit of the “LM” level to the non-selected word line WLns.

The controller 5 applies the voltage Vdd on the select gate line SGS, and the memory cells MC with the threshold voltage of the memory cells MC higher than the verification voltage VCG_LMV are turned off. Consequently, the bit lines BL are on the high level. The cells with the threshold voltage lower than the verify voltage VCG_LMV are turned on. Consequently, the bit lines BL become the low level (ground voltage Vss). Here, a determination is made regarding the memory cells MC written to the “LM” level. In this case, when the memory cells MC is finished writing to the “LM” level, the controller 5 is set “1” data (i.e., the write operation is not carried out) in the data latch of the bit lines BL.

### (Determination: ST14)

When all of the data latches become “1” data (i.e., write operation is not carried out), or when more than a prescribed number of them become “1” data, the controller 5 terminates the write operation (Y in ST14). Otherwise, the controller 5 once again carries out the program operation (ST12) (N in ST14). In this case, the write voltage VPGM is stepped up to carry out the write operation.

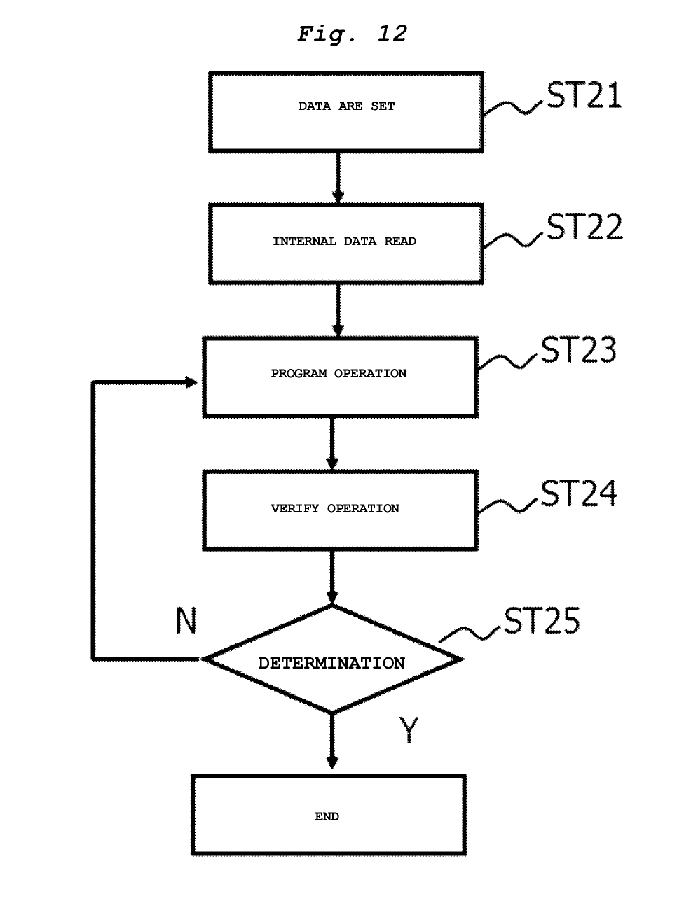

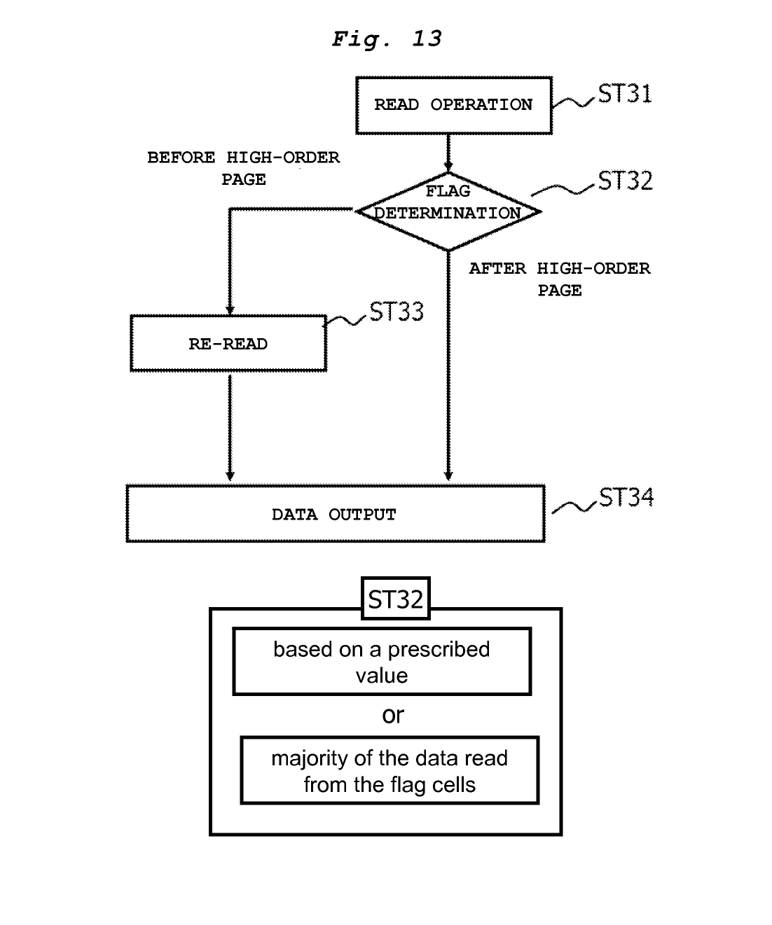

In the following, the data write of the high-order page will be explained with reference to FIG. 12. FIG. 12 is a flow chart illustrating an example of the data write operation of the high-order page.

### (Data Set: ST21)

For the data write operation of the high-order page, the address ADD is sent from the host or memory controller HM. The address ADD is the address of the page PG where the data of the low-order page are written. The controller 5 and the word line controller 3 select the page PG according to the address ADD.

Then, the write data are input from the host or memory controller HM, and the write data are stored in the data latches in the bit line controller 2. Here, as the operation is the data write operation of the high-order page, data are written in the flag cells FC. Consequently, the host or memory controller HM sends the “0” data (i.e., write operation is carried out) to the data latch of the bit line BL connected to the flag cell FC. Also, the controller 5 sets the “0” data in the data latch of the bit line BL connected to the flag cell FC.

### (Internal Data Read: ST22)

A determination is made regarding whether the threshold voltage of the memory cells MC of the low-order page belongs to the “E” level or “LM” level. Here, the controller 5 carries out the internal read operation. The controller 5 and the bit line controller 2 charge the bit lines BL to the high level. Also, the controller 5 applies VCG_AR1 to the selected word line WLs, and it applies the read voltage Vread to the non-selected word line WLns.

The controller 5 applies the power supply voltage Vdd to the select gate line SGS. The memory cells MC with the threshold voltage of the memory cells MC higher than the verification voltage VCG_LMV are turned off. Consequently, the bit lines BL keep the high level. Also, the cells with the threshold voltage of the memory cells MC lower than the verification voltage VCG_LMV are turned on. Consequently, the bit lines BL become the low level (ground voltage Vss). Here, the data latches connected to the bit lines BL stored the data on the high level or the low level. Also, the data latches that store the result of the internal data read may be data latches other than the data latches that store the write data.

In addition, one may also adopt a scheme in which the controller 5 reads the data from the flag cells FC and stores the results in the data latches or the controller 5 may not read the data from the flag cells FC.

### (Program Operation: ST23)

As the command written from the host or memory controller HM is input, the data write operation is started in the memory cells MC. On the basis of a result of the internal data read, when the threshold voltage of the memory cells MC belongs to the “E” level, if the data stored in the data latches are the “1” data, the controller 5 keeps the threshold voltage of the memory cells MC on the “E” level as is; if the data stored in the data latches are the “0” data, the controller 5 shifts the threshold voltage of the memory cells MC to the “A” level.

Also, when the threshold voltage of the memory cells MC belongs to the “LM” level, if the data stored in the data latches are the “1” data, the controller 5 shifts the threshold voltage of the memory cells MC to the “B” level; when the data held in the data latches are the “0” data, the controller 5 shifts the threshold voltage of the memory cells MC to the “C” level.

Also, the controller 5 shifts the threshold voltage of the flag cells FC to the “B” level. In this case, one may also adopt a scheme in which the data of the data latches connected to the flag cells FC are taken as reference, and the threshold voltage of the flag cells FC is shifted to the “B” level independent of the data in the data latches.

The program operation is the same as the program operation of the low-order page (ST12). In addition, the data latches of the bit lines BL connected to the memory cells MC and flag cells FC that shift the threshold voltage are set by the controller 5 to the “0” data (i.e., write operation is carried out), and the data latches of the bit lines BL connected to the memory cells MC that do not shift the threshold voltage are set at the “1” data (i.e., write operation is not carried out). That is, the memory cells MC and the flag cells FC belonging to the same page PG may similarly shift the threshold voltage.

### (Verify Operation: ST24)

The verification operation is carried out after the program operation. In the verification operation of the high-order page, a determination of the “A” to “C” levels is continuously carried out. The controller 5 and the bit line controller 2 can charge the bit lines BL to the high level. First of all, the controller 5 applies the verification voltage VCG_AV to the selected word line WLs. Here, a determination is made regarding the memory cells MC written to the “A” level. In this case, when the memory cells MC is finished writing to the “A” level, the controller 5 sets the “1” data (i.e., the write function is not carried out) to the data latches of the bit lines BL. Similarly, a determination is made regarding the memory cells MC and the flag cells FC written to the “B” level. Here, when the memory cells MC is finished writing to the “B” level, the controller 5 sets the “1” data (i.e., the write function is not carried out) to the data latches of the bit lines BL. Also, once the flag cells FC are written to the “B” level, the controller 5 sets the “1” data (i.e., the write function is not carried out) to the data latches of the bit lines BL. Similarly, a determination is made regarding the memory cells MC written to the “C” level. Here, when the memory cells MC is finished writing to the “C” level, the controller 5 sets the “1” data (i.e., the write function is not carried out) to the data latches of the bit lines BL.

On the other hand, the controller 5 maintains the data latches of the memory cells MC that have not been written to the prescribed level on the “0” level.

In addition, the memory cells MC and the flag cells FC can simultaneously carry out the verification operation.

### (Determination: ST25)

When all of the data latches are of the “1” data (i.e., the write function is not carried out), or when over a prescribed number of the data latches are of the “1” data, the controller 5 terminates the write operation (Y in S25). Otherwise, the controller 5 once again carries out the program operation (S23) (N in S25). In this case, it is also possible to step up the write voltage VPGM to carry out the write operation.

In the following, data read of the low-order page will be explained with reference to FIG. 13. FIG. 13 is flow chart illustrating an example of the data read operation of the low-order page of the nonvolatile semiconductor storage device according to this embodiment.

### (Read Operation: ST31)

First of all, the address ADD is sent from the host or memory controller HM. Here, the address ADD is the address of the data written in the low-order page. The controller 5 and the word line controller 3 select the page PG according to the address ADD (the page is called selected page PGs). Here, the controller 5 and the bit line controller 2 set the bit lines BL to the high level. The controller 5 applies the read voltage VCG_BR3 to the selected word line WLs. Also, the controller 5 applies the read voltage Vread, which is higher than the upper limit of the “C” level, to the non-selected word line WLns.

The controller 5 applies the power supply voltage Vdd to the select gate line SGS. The memory cells MC with the threshold voltage of the memory cells MC higher than the read voltage VCG_BR3 are turned off. Consequently, the bit lines BL are kept on the high level. On the other hand, the memory cells MC with the threshold voltage lower than the read voltage VCG_BR3 are turned on. Consequently, the bit lines BL become the low level (ground voltage Vss). This result is stored and retained in the data latches.

Here, it is possible to simultaneously read the plural memory cells MC and the plural flag cells FC belonging to the selected page PGs. As a result, the results of reading the data from the plural memory cells MC and the plural flag cells FC are kept in the data latches.

### (Flag Determination: ST32)

It is necessary to determine whether the selected page PGs is after the high-order page. Here, the controller 5 uses the data stored in the flag cells FC to determine whether the selected page PGs is before the high-order page or after the high-order page. Here, the data about whether the selected page PGs is before the high-order page or after the high-order page is called “flag data”.

In this embodiment, plural flag cells FC are arranged in each of the plural redundant regions 12-1 to 12-3. Here, the controller 5 determines whether the flag data refers to the decision based on the majority of the data read from the flag cells FC or whether the number of the flag cells FC having “0” data written in them is over a prescribed value. This flag determination will be explained in detail later.

The determination of majority may be carried out using the conventional bit number counter and the majority deciding circuit, respectively.

### (Re-Read: ST33)

In the step ST32, when the page is determined to be before the high-order page from the flag data, the write operation of the high-order page is not carried out. Consequently, distribution of the threshold voltage of the memory cells MC become that shown in FIG. 9A. Consequently, when the controller 5 reads the data from the memory cells MC, the controller 5 applies the read voltage VCG_AR1 (or VCG_AR3) to the selected word line WLs. Here, the read operation of data from the memory cells MC is carried out again. The resulting read data are held in the data latches. Then, the controller 5 outputs the data stored in the data latches to the host or memory controller HM (ST34).

On the other hand, in step S32, when it is determined that, from the flag data that the page is after the high-order page, the write operation of the high-order page is carried out. As a result, the threshold voltage distribution of the memory cells MC becomes that shown in FIG. 9B. Consequently, there is no need to re-read the data from the memory cells MC. As a result, the controller 5 outputs the data held in the data latches to the host or memory controller HM (ST34).

In addition, when the high-order page is read, the controller 5 can calculate the flag data by using the flag cells FC, just as in the case of the low-order page. Then, the controller 5 checks after the high-order page using data of flag cells, and the read voltages VCG_AR, VCG_CR are used to read the data of the selected memory cell MCs. Here, the data read from the flag cells FC and calculation of the flag data may be omitted in this case. As a result, it is possible to increase the speed of the read operation.

### (First Flag Determination Method)

The controller 5 uses the data of all of the flag cells FC belonging to the selected page PGs to determine the flag data. Here, the redundant regions 12 are arranged to be dispersed in the memory cell array 1. Consequently, the plural flag cells FC are also arranged to be dispersed in the memory cell array 1.

For example, when the number of the flag cells FC with a threshold voltage higher than the read voltage VCG_BR3 is greater than the number of the flag cells FC having a threshold voltage lower than the read voltage VCG_BR3, the controller 5 determines that the selected page PG is after the high-order page. On the other hand, when the number of the flag cells FC with a threshold voltage greater than the read voltage VCG_BR3 is smaller than the number of the flag cells FC having a threshold voltage lower than the read voltage VCG_BR3, the controller 5 determines that the selected page PG is before the high-order page.

More specifically, in the selected page PGs of the nonvolatile semiconductor storage device according to the present embodiment, p (p is a natural number of 3 or larger) flag cells are arranged. Here, when the number of the flag cells FC having a threshold voltage lower than the read voltage VCG_BR3 is larger than p/2, it is determined that the selected page PGs is before the high-order page. Also, when the number of the flag cells FC is an even number, one may also adopt a scheme in which the prescribed value is set at 3/4*p; when the number of the flag cells FC having a threshold voltage greater than the read voltage VCG_BR3 is larger than the product of 3/4*p, it is determined that the selected page PGs is before the high-order page.

Here, the probability that all of the flag cells FC are defective is very small. In addition, even when a portion of the flag cells FC become defective as a result of particles, it is possible to determine the flag data without using a defective flag cells FC. Also, by determining the data of the plural flag cells FC based on the majority of data, it is possible to increase the reliability of the flag data. As a result, it is possible to improve the manufacturing yield of the nonvolatile semiconductor storage device.

### (Second Flag Determination Method)

The controller 5 selects a typical redundant region among the redundant regions 12-1 to 12-n and determines the flag data. For example, the controller 5 determines the flag data by using the plural flag cells FC arranged in the redundant region 12 near the side where the word line controller 3 is arranged.

At the point far away from the word line controller 3, the voltage is dropped due to the resistance of the selected word line WLs. Consequently, the data stored in the flag cells FC may not be assessed correctly. On the other hand, the potential is rarely dropped due to the resistance of the selected word line WLs at place at the position near the word line controller 3. Consequently, the controller 5 can correctly determine the data stored in the flag cells FC.

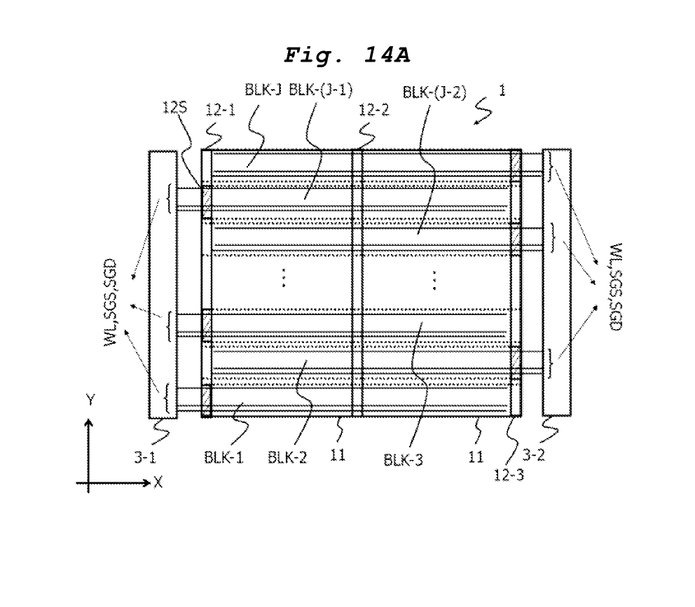

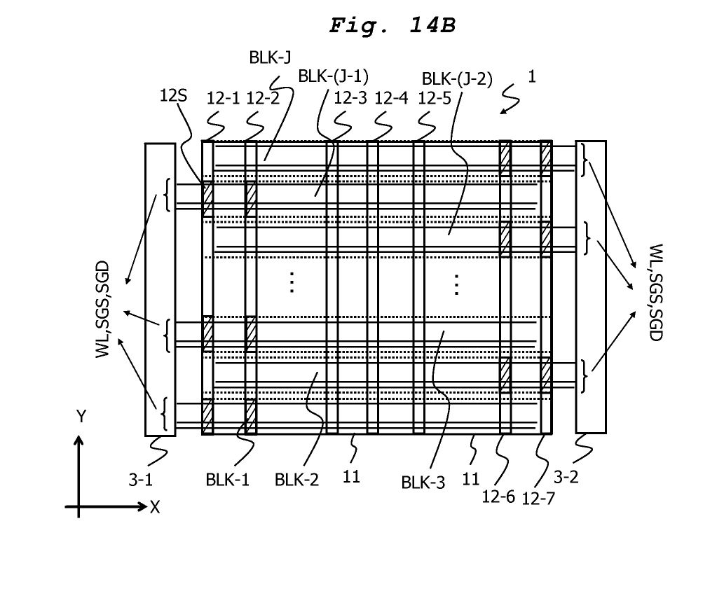

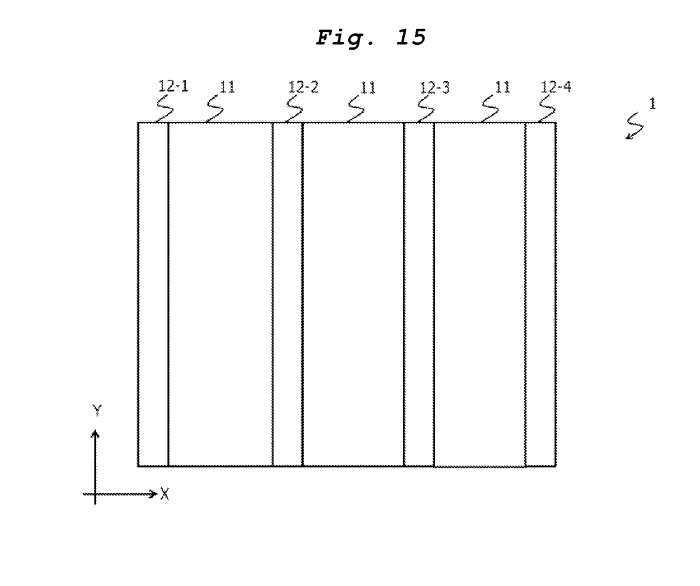

For example, as shown in FIG. 14A, the position in which the word line controller 3 is connected for each block may change. As shown in FIG. 14A, for the memory cell array 1, J (J is a natural number of 2 or larger) blocks BLK are arranged in the Y-direction. Here, the word lines WL and the selected gate lines SGS, SGD of the odd-numbered blocks BLK are connected to the word line controller 3-1 on the left-hand side in the X-direction. On the other hand, the word lines WL and the selected gate lines SGS, SGD of the even-numbered blocks BLK are connected to the word line controller 3-2 on the right-hand side in the X-direction. In this case, the controller 5 determines the flag data by using the flag cells FC of the redundant region 12S arranged at a position near the word line controller 3. As shown in FIG. 14A, the redundant region 12S of the odd-numbered blocks BLK is arranged in the word line controller 3-1, and the redundant region 12S of the even-numbered blocks BLK is arranged in the word line controller 3-2.

For example, the controller 5 carries out decision based on the majority of data or the determination on whether the value is larger than the prescribed value for the data read from the plural flag cells FC of the redundant region 12S arranged at a position near the word line controller 3. More specifically, the controller 5 uses the threshold voltage of the flag cells FC arranged in the redundant region 12S to make the following determination: when the number of the flag cells FC that have a threshold voltage greater than the read voltage VCG_BR3 is more than the number of the flag cells FC having a threshold voltage lower than the read voltage VCG_BR3, it determines that the selected page PG is after the high-order page. On the other hand, the controller 5 uses the threshold voltage of the flag cells FC arranged in the redundant region 12S to make the following determination: when the number of the flag cells FC having a threshold voltage greater than the read voltage VCG_BR3 is less than the number of the flag cells FC having a threshold voltage lower than the read voltage VCG_BR3, it determines that the selected page PG is before the high-order page. As a result, it is possible to make a correct determination of the flag data.

Also, the controller 5 may use plural redundant regions 12S to determine the flag data. For example, in the case shown in FIG. 14B, two redundant regions 12 near the word line controller 3 are in use. As redundant regions 12 arranged at plural sites are adopted to determine the flag data, it is possible to make a correct determination of the flag data.

### (Third Flag Determination Method)

The controller 5 calculates the first flag data in each of the redundant regions 12-1 to 12-n, and it uses the first flag data to finally determine the flag data.

For example, localized thinning or opening may take place in the word lines WL. The sites where localized thinning or opening are called abnormal sites. In this case, as viewed from the word line controller 3, it is impossible to make a correct reading of the data from the memory cells MC and flag cells FC ahead of the abnormal sites of the word lines WL. However, if they are the memory cells MC that store the user data, a reading may be carried out by a correction known as ECC (Error-Correcting Code). On the other hand, in many cases, due to an increase in the operation speed and a reduction of the parity bits, the flag cells FC are excluded from the subjects of correction by ECC.

For example, suppose redundant region 12-1 is nearest to the word line controller 3 while abnormal sites take place on the word lines WL in the redundant region 12-(k-1) and redundant region 12-k. In this case, it is impossible to correctly read the data of the flag cells FC belonging to the redundant region 12-k. On the other hand, it is possible to correctly read the data of the flag cells FC belonging to the redundant regions 12-1 to 12-(k-1).

For example, as depicted in FIG. 17, the controller 5 makes a decision based on the majority of data or the determination regarding whether the value is greater than the prescribed value for the data read from the plural flag cells FC of each of the redundant regions 12-1 to 12-k. More specifically, the controller 5 uses the threshold voltage of the flag cells FC arranged in the redundant regions 12-1 to 12-k to perform the following operation: when the number of the flag cells FC having a threshold voltage greater than the read voltage VCG_BR3 is more than the number of the flag cells FC having a threshold voltage lower than the read voltage VCG_BR3, it takes the first flag data as the “0” data. On the other hand, the controller 5 uses the threshold voltage of the flag cells FC arranged in the redundant regions 12-1 to 12-k to perform the following operation: when the number of the flag cells FC having a threshold voltage greater than the read voltage VCG_BR3 is less than the number of the flag cells FC having a threshold voltage lower than the read voltage VCG_BR3, it takes the first flag data as the “1” data. As a result, k first flag data are calculated (ST32A in FIG. 17).

The controller 5 calculates the final flag data on the basis of the decision based on the majority of data or the determination regarding whether the value is greater than the prescribed value for k first flag data (ST32B in FIG. 17). As a result, even when defects occur in the flag cells FC of a portion of the redundant regions 12, it is still possible to make a correct decision regarding the flag data.

### (Modified Example of the Flag Determination Method)

Each of the redundant regions 12-1 to 12-k has plural flag cells FC. Here, due to the data pattern, the flag cells FC adjacent to the memory cell array regions 11 may have poor data reliability.

Here, the controller 5 makes a decision based on the majority of data for the flag cells FC in each of the redundant regions 12-1 to 12-k (except for the flag cells FC at the two ends); alternatively, it makes a determination based on whether the value is greater than the prescribed value. In this modified example, the first through third determination methods maybe adopted. As a result, it is possible to increase the reliability of the flag data.

### (Positions for the Arrangement of the Redundant Regions)

It is preferred that the redundant regions 12-1 to 12-k be evenly arranged in the memory cell array 1. This arrangement can cope with the random defects that occasionally take place in the memory cell array.

However, because the memory cell array 1 has a repetitious pattern, there may be defects concentrated in the end portion of the memory cell array 1 and concentrated in the central portion of the cell array in the word line direction.

Here, as shown in FIG. 2, when the redundant regions are arranged in at least three sites including the two end portions and the central portion of the memory cell array 1, it is possible to increase the manufacturing yield of the nonvolatile semiconductor storage device. That is, when defects are concentrated in the end portions of the memory cell array 1, it is possible to assess the flag data by the flag cells arranged in the central portion of the memory cell array 1. In addition, when the defects take place concentrated in the central portion of the memory cell array 1, it is possible to assess the flag data by the flag cells FC of the redundant regions 12 arranged in the end portion of the memory cell array 1.

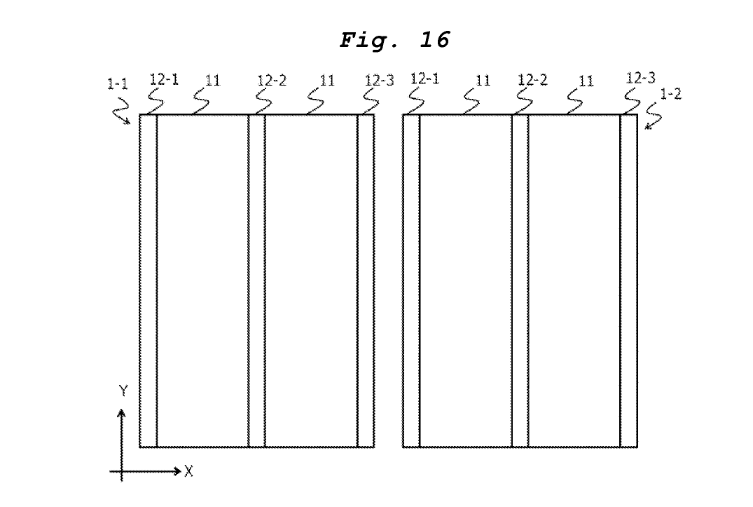

Also, as shown in FIG. 15, it is possible to arrange the redundant regions 12 in at least the two end portions of the memory cell array 1 and at two sites other than the two end portions. That is, it is possible to arrange the redundant regions 12 at sites other than the sites prone to concentrated defects. In the example shown in FIG. 15, the redundant regions 12-2 and 12-3 correspond to the sites where a concentration of defects hardly takes place. As a result, even when defects take place in the two end portions and in the central portion, it is still possible to determine the flag data by the flag cells FC of the redundant regions 12 arranged outside of the two end portions and the central portion. In the scheme shown in FIG. 15, the redundant regions are arranged at the two end portions and at two sites other than the two end portions. However, one may also adopt a scheme in which they are arranged at least in the two end portions and one site other than the two end portions. This scheme can realize the same effect as mentioned previously. In addition, the effect can be realized when the redundant regions 12-1, 12-4 at the two end portions are not included.

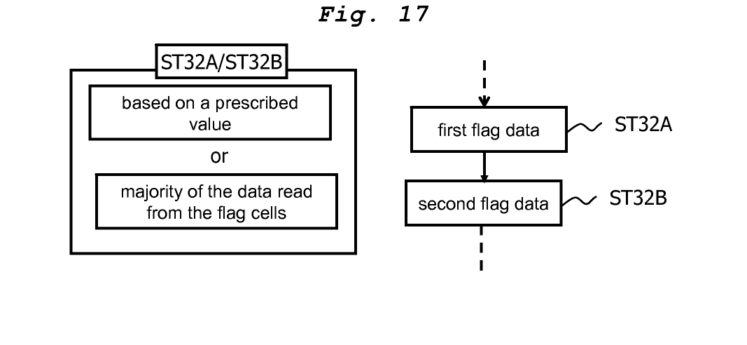

As shown in FIG. 16, the nonvolatile semiconductor storage device may also have plural memory cell arrays 1 (memory cell arrays 1-1 and 1-2). In this case, in the X-direction, there are two end portions of the memory cell arrays 1-1 and 1-2 at the end portion of the semiconductor storage device and on the side opposite to the end portion of the semiconductor storage device (the central portion).

Here, as shown in FIG. 16, when the redundant regions are arranged at three sites of the memory cell array 1, that is, at the two end portions and the central portion, for the overall nonvolatile semiconductor storage device, the redundant regions 12 are arranged at the two end portions, the central portion, and the regions other than the two end portions and the central portion. As a result, it is possible to increase the manufacturing yield of the semiconductor storage device. Also, by decreasing the number of the redundant regions 12, it is possible to decrease the size of the nonvolatile semiconductor storage device. In the case shown in FIG. 16, there are two memory cell arrays 1. However, the effect also can be realized when there are three or more memory cell arrays 1.

While certain embodiments have been described, these embodiments have been presented by way of example only and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile semiconductor storage device comprising:
a memory cell array including a plurality of redundancy regions with flag cells arranged in a first direction, a plurality of word lines extending in the first direction and a plurality of bit lines extending in a second direction crossing the first direction; and
a controller configured to control writing of data to the memory cell array and to one or more of the flag cells.

2. The nonvolatile semiconductor storage device according to claim 1, wherein
the plurality of word lines are arranged in the second direction,
a memory cell string includes memory cells arranged side by side in the second direction,
a flag cell string includes flag cells arranged side by side in the second direction, and
the plurality of bit lines are electrically connected to one end of the memory cell string and the flag cell string.

3. The nonvolatile semiconductor storage device according to claim 1, wherein the plurality of redundancy regions are arranged in at least two end portions of the memory cell array and at another location other than the two end portions, the two end portions of the memory cell array being separated from each other in the first direction.

4. The nonvolatile semiconductor storage device according to claim 1, wherein the controller is configured to generate flag data using data stored in the flag cells in at least one redundancy region among the plurality of redundancy regions.

5. The nonvolatile semiconductor storage device according to claim 1, wherein
each of the plurality of redundancy regions has a plurality of flag cells; and
the controller is configured to generate a plurality of first flag data using data stored in the plurality of flag cells in each of the plurality of redundancy regions, and to generate second flag data using the plurality of first flag data.

6. The nonvolatile semiconductor storage device according to claim 5, wherein the first flag data is generated based on a majority of data stored in the plurality of flag cells in each of the plurality of redundancy regions.

7. The nonvolatile semiconductor storage device according to claims 6, wherein the second flag data is generated based on a majority of the plurality of the first flag data.

8. The nonvolatile semiconductor storage device according to claim 6, wherein the second flag data is generated based on whether or not the number of the first flag data that has been generated is larger than a prescribed value.

9. The nonvolatile semiconductor storage device according to claim 5, wherein the first flag data is generated based on whether or not the number of the plurality of flag cells in each of the plurality of redundancy regions having data stored therein is larger than a prescribed value.

10. The nonvolatile semiconductor storage device according to claim 9, wherein the second flag data is generated using a majority of the plurality of the first flag data.

11. The nonvolatile semiconductor storage device according to claim 9, wherein the second flag data is generated based on whether or not the number of the plural pieces of first flag data that has been generated is larger than a prescribed value.

12. The nonvolatile semiconductor storage device according to claims 1, wherein
the controller is configured to generate flag data using data stored in the flag cells in the plurality of redundancy regions.

13. The nonvolatile semiconductor storage device according to claim 12, further comprising:
a word line controller disposed on a side of the memory cell array, wherein
the word line controller is configured to generate flag data using the data stored in the flag cells of a redundancy region of the plurality of redundancy regions that is nearest to the word line controller.

14. The nonvolatile semiconductor storage device according to claim 12, further comprising:
a word line controller disposed on a side of the memory cell array; and
the word line controller is configured to generate flag data using the data stored in the flag cells of redundancy regions of the plurality of redundancy regions that are near the side where the word line controller is disposed.

15. The nonvolatile semiconductor storage device according to claim 1, wherein the redundancy regions are spaced apart evenly in the memory cell array.
